(19) United States
(12) Patent Application Publication
(10) Pub. No.: US 2012/0171797 A1
(43) Pub. Date: Jul. 5, 2012

(54) SEASONING OF DEPOSITION CHAMBER FOR DOPANT PROFILE CONTROL IN LED FILM STACKS

(75) Inventors: Sang Won KANG, San Jose, CA (US); Jie SU, Edison, NJ (US); Jie CUI, Albany, CA (US); Juan CAI, Sunnyvale, CA (US)

(73) Assignee: APPLIED MATERIALS, INC., Santa Clara, CA (US)

(21) Appl. No.: 13/313,287

(22) Filed: Dec. 7, 2011

Related U.S. Application Data
(60) Provisional application No. 61/421,141, filed on Dec. 8, 2010.

(51) Int. Cl. H01L 33/02

(52) U.S. Cl. 438/47; 257/E33.023

(57) ABSTRACT

Apparatus and method for seasoning an idled deposition chamber prior to growing an epitaxial layer. A dopant containing source gas, such as a Mg-containing source gas, is introduced to an MOCVD chamber after the chamber has been idled and prior to the chamber growing a film containing the dopant on a substrate. In a multi-chambered deposition system, a non-p-type epitaxial layer of an LED film stack is grown over a substrate in a first deposition chamber while a seasoning process is executed in a second deposition chamber with a p-type dopant-containing source gas. Subsequent to the seasoning process, a p-type epitaxial layer of the LED film stack is grown on the substrate in the second deposition chamber with improved control of p-type dopant concentration in the p-type epitaxial layer.

### CROSS REFERENCE TO RELATED APPLICATIONS

This application claims the benefit of U.S. Provisional Application No. 61/421,141 filed on Dec. 8, 2010, entitled “SEASONING OF DEPOSITION CHAMBER FOR DOPANT PROFILE CONTROL IN LED FILM STACKS,” the entire contents of which are hereby incorporated by reference in its entirety for all purposes.

### FIELD

Embodiments of the present invention pertain to the field of light-emitting diode (LED) fabrication and, in particular, to growth LED film stacks.

### DESCRIPTION OF RELATED ART

Often, materials are difficult to grow or deposit in succession to form an LED film stack including both n-type and p-type layers. While it is desirable to form sharp material interfaces, for example between complementary doped regions of an LED film stack, various deposition processes may be subject to turn-on delay for dopants, particularly magnesium (Mg) in p-type doped layers. Depending on the processing history of a particular deposition chamber, a dopant concentration of an initial portion of a grown film may deviate from that of a portion grown after the deposition chamber equilibrates during the film growth. Such deviation in the initial dopant concentration may reduce the sharpness of material interfaces and adversely affect LED film stack performance. Furthermore, the dependence of a doped layer's initial dopant concentration on chamber history may increase variation in LED film stack performance.

### BRIEF DESCRIPTION OF THE DRAWINGS

Embodiments of the present invention is illustrated by way of example, and not by way of limitation, in the figures of the accompanying drawings, in which:

FIG. 1A is a flow diagram illustrating a multi-chamber method for epitaxial growth of doped films and undoped films, in accordance with an embodiment of the present invention;

FIG. 1B illustrates a cross-sectional view of a GaN-based LED film stack, in accordance with an embodiment of the present invention;

FIG. 1C is a flow diagram illustrating a method for epitaxial growth of the GaN-based LED film stack depicted in FIG. 1B, in accordance with an embodiment of the present invention;

FIG. 1D illustrates a timing diagram for processes performed in deposition chambers of a multi-chambered deposition system, in accordance with an embodiment of the present invention;

FIG. 2 illustrates a dopant concentration profile of an LED film stack, in accordance with an embodiment of the present invention;

FIG. 3 illustrates a graph of radiometric power for a doped layer, in accordance with an embodiment of the present invention;

FIG. 4 is a schematic plan view of a multi-chambered deposition system, in accordance with an embodiment of the present invention; and

FIG. 5 is a schematic of a computer system which may serve as a controller in the multi-chambered deposition system depicted in FIG. 4, in accordance with an embodiment of the present invention.

### SUMMARY OF DESCRIPTION

LEDs and related devices may be formed of a stack of materials, such as group III-V semiconductors. Exemplary embodiments of the present invention relate to seasoning or conditioning of a deposition chamber in preparation for growth of LED material layers in group LED film stacks, such as, but not limited to gallium nitride (GaN) films.

In an embodiment, a multi-chambered growth process separates or “splits” growths of different LED film stack layers into different chambers, for example, to avoid cross contamination between dopant species, such as between In and Mg and between Mg and Si.

In an embodiment, a first deposition chamber is seasoned with a source gas containing a first dopant while either no substrate or a dummy substrate is disposed in the first deposition chamber in preparation for epitaxially growing, in the first deposition chamber, a doped layer of the LED film stack, the doped layer also having the first dopant. In one such embodiment, a layer doped with p-type dopant (e.g., pGaN doped with Mg) is grown in the first epitaxial chamber of the multi-chambered deposition system while a layer substantially free of p-type dopant (e.g., undoped GaN or a complementary doped layer such as nGaN) is grown in a second deposition chamber of the multi-chambered deposition system. For one embodiment, a Mg doped layer is grown over a non-Mg doped layer to form an abrupt p-type to non-p-type material junction. For example, a multiple quantum well (MQW) structure is completed with a growth of an undoped GaN (uGaN) barrier in the first deposition chamber and a Mg doped pGaN or pAlGaN layer is grown on the uGaN layer in the second deposition chamber.

In further embodiments where the first deposition chamber is placed in an idle state for a period of time, for example while the second deposition chamber is executing a growth of an MQW structure and an undoped barrier layer, a chamber seasoning process is executed by the first deposition chamber. Exemplary chamber seasoning processes introduce one or more source gases containing the same dopant used by the first deposition chamber for growth of the doped epitaxial layer. For example, where the first chamber is to grow a Mg doped pGaN or pAlGaN layer, a Mg-doped source gas is introduced into the first deposition chamber during the seasoning process. In further embodiments, a chamber purge may be performed by the first deposition chamber while in an idle state with a chamber seasoning process performed as the chamber exits the idle state in preparation for depositing a film on a workpiece during an active state.

Embodiments of multi-chambered deposition systems include a first deposition chamber to grow a first epitaxial layer over a substrate, the first epitaxial layer containing a dopant, a second deposition chamber to grow second epitaxial layer over the substrate, the second epitaxial layer substantially free of the dopant, and a controller to cause the second deposition chamber to execute a seasoning process introducing a source gas containing the dopant into the first deposition chamber while either no substrate or a dummy substrate is disposed in the first deposition chamber. The controller may further cause the first deposition chamber to execute an inert gas purge prior to executing the seasoning process and to then initiate execution of a chamber seasoning process based on at least one of: an elapsed idle time of the deposition chamber, an elapsed growth time of an epitaxial layer being grown in another deposition chamber of the system, or a time to completion of a growth executed in another deposition chamber of the system.

### DETAILED DESCRIPTION

In the following description, numerous details are set forth. It will be apparent, however, to one skilled in the art, that the present invention may be practiced without these specific details. In some instances, well-known methods and devices are shown in block diagram form, rather than in detail, to avoid obscuring the present invention. Reference throughout this specification to “an embodiment” means that a particular feature, structure, function, or characteristic described in connection with the embodiment is included in at least one embodiment of the invention. Thus, appearances of the phrase “in an embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not mutually exclusive.

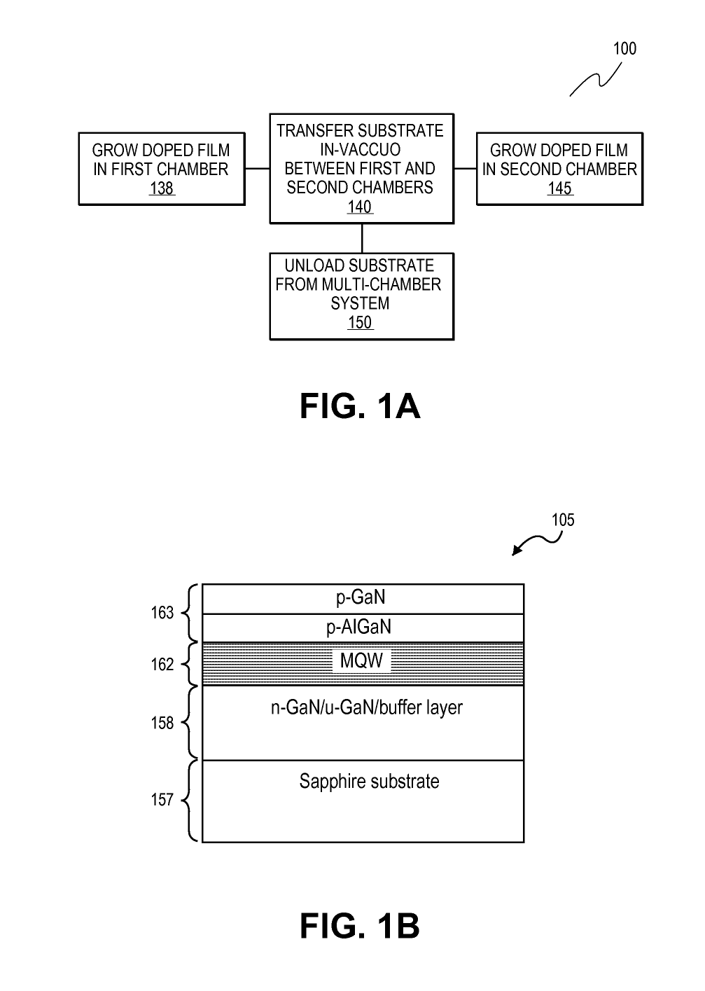

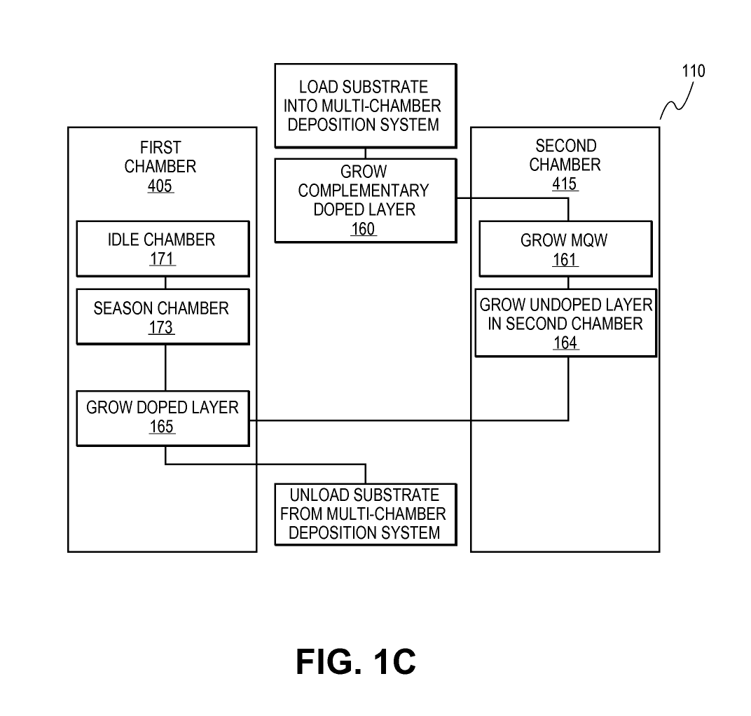

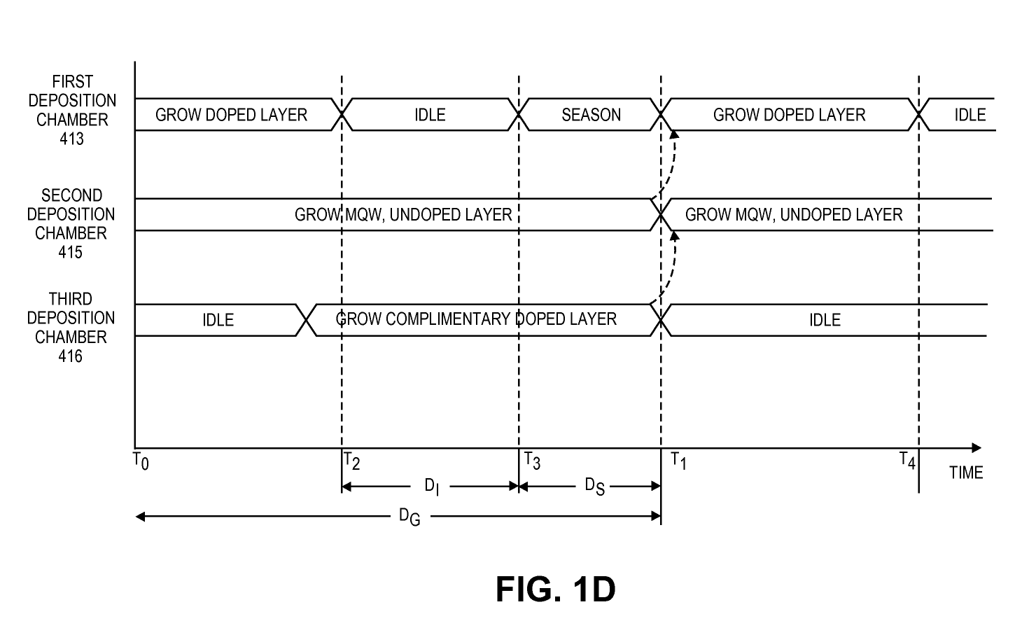

In certain embodiments, an LED film stack is grown in a multi-chamber process 100 employing a dedicated chamber approach as illustrated in FIG. 1A. In the multi-chamber process 100, layers in an LED film stack are grown in a sequence of separate deposition chambers. For example, a doped film is epitaxially grown on a substrate in a first chamber at operation 138, and an undoped layer is grown on the substrate in a second chamber 145 with a transfer between the first and second chambers occurring under vacuum at operation 140 and the direction of transfer depending on the film stack desired and corresponding chamber sequencing. Subsequent to growing the LED film stack, the multi-chamber process 100 completes with unloading the substrate from the multi-chamber deposition system at operation 150. While numerous examples are provided herein of a modular chamber approach in which a transfer chamber module couples a plurality of chambers to form a multi-chamber deposition system commonly referred to as a cluster tool, it is to be appreciated that an in-line epitaxial system in which a substrate is conveyed from a first chamber portion to a second chamber portion between epitaxial depositions may also be utilized to practice the split-chambered embodiments of invention described herein.

It has been found that the dopant concentration profile in the doped film grown at operation 138 may be improved through seasoning of the first chamber just prior to forming the doped film in the event that the first chamber is idled, for example to accommodate sequencing of the first and second chambers to form an LED film stack. While pre-process seasoning of a deposition chamber as described herein provides advantages to a multi-chambered LED film stack growth process in which process times between chambers may not be equal, it should be appreciated that single chamber processes may also benefit from the seasoning processes described herein. For example, in a single chamber process where layers of differing composition are grown successively as different steps of a growth recipe executed within the single chamber, the dopant concentration profile of the initial layer grown in the single chamber process sequence can be affected by pre-growth chamber seasoning in substantially the same manner as for the multi-chambered process. Therefore, where a dopant concentration profile of any initial epitaxial layer grown by a deposition chamber is important, whether a part of a multi-chamber film stack growth process, or not, the pre-growth seasoning processes described herein are advantageous.

In an embodiment, the pre-growth chamber seasoning described herein may be performed in addition to a post-chamber clean seasoning which might be performed. For example, where a wet clean or an in-situ (e.g., Cl₂-based) clean is periodically performed on a deposition chamber, an initial seasoning process may be performed before the deposition chamber is brought online for substrate processing. In an embodiment, an initially seasoned deposition chamber which is idled for more than a few minutes after being brought online is further seasoned just prior to performing a growth on a substrate.

FIG. 1B illustrates a cross-sectional view of a GaN-based LED film stack 105 grown using a multi-chamber process, in accordance with an embodiment of the present invention. The LED film stack 105 is merely exemplary as the advantages of the abrupt junctions achievable with the multiple-chamber process 100 maybe leveraged by an artisan to form other LED film stacks. For example, the film stack 105 may be inverted to have an n-type layer disposed over an MQW structure and p-type layer. As another example, a multi-junction LED film stack may also be formed including a plurality of MQW structures and a plurality of at least one of n-type and p-type material layers.

In FIG. 1B, the LED film stack 105 is grown on a substrate 157. The various layers may be grown in a metalorganic chemical vapor deposition (MOCVD) chamber or a hydride/halide vapor phase epitaxy (HVPE) chamber, or another chamber known in the art to form such films. Any growth techniques known in the art may be utilized with such chambers. In one implementation, the substrate 157 is single crystalline sapphire. Other embodiments include the use of substrates other than sapphire substrates, such as, Silicon (Si), germanium (Ge), silicon carbide (SiC), gallium arsenide (GaAs), zinc oxide (ZnO), lithium aluminum oxide (γ-LiAlO₂). Upon the substrate 157, is one or more base layers 158 which may include any number of group III-nitride based materials, such as, but not limited to, GaN, InGaN, AlGaN. The substrate and buffer layers may provide either a polar GaN starting material (i.e., the largest area surface is nominally an (h k l) plane wherein h=k=0, and l is non-zero), a non-polar GaN starting material (i.e., the largest area surface oriented at an angle ranging from about 80-100 degrees from the polar orientation described above towards an (h k l) plane wherein l=0, and at least one of h and k is non-zero), or a semi-polar GaN starting material (i.e., the largest area surface oriented at an angle ranging from about >0 to 80 degrees or 110-179 degrees from the polar orientation described above towards an (h k l) plane wherein l=0, and at least one of h and k is non-zero). One or more bottom n-type epitaxial layers are further included in the base layer 158 to facilitate a bottom contact. The bottom n-type epitaxial layers may be any n-type group III-nitride based materials, such as, but not limited to, GaN, InGaN, AlGaN.

As further depicted in FIG. 1B, a multiple quantum well (MQW) structure 162 is disposed over the base layer 158. The MQW structure 162 may be any known in the art to provide a particular emission wavelength. In a certain embodiments, the MQW structure 162 may have a wide range of indium (In) content within GaN. For example, depending on the desired wavelength(s), the MQW structure 162 may have between about a 10% to over 40% of mole fraction indium as a function of growth temperature, ratio of indium to gallium precursor, etc. It should also be appreciated that any of the MQW structures described herein may also take the form of single quantum wells (SQW) or double hetereostructures that are characterized by greater thicknesses than a QW.

One or more p-type doped epitaxial layers 163 are disposed over the MQW structure 162. The p-type doped epitaxial layers 163 may include one or more layers of differing material composition. In the exemplary embodiment, the p-type epitaxial layers 163 include both p-type GaN and p-type AlGaN layers doped with Mg. In other embodiments only one of these, such as p-type GaN are utilized. Other materials known in the art to be applicable to p-type contact layers for GaN systems may also be utilized. The thicknesses of the p-type doped epitaxial layers 163 may also vary within the limits known in the art. The p-type doped epitaxial layers 163 may also be gown in an MOCVD or HVPE epitaxy chamber. Incorporation of Mg during the growth of the p-type doped epitaxial layers 163 may be by way of introduction of cp₂Mg to the epitaxy chamber, for example. In an embodiment, the p-type doped epitaxial layers 163 are grown using a different epitaxial chamber as was used for the MQW structure 162.

Additional layers, such as, tunneling layers, n-type current spreading layers and further MQW structures (e.g., for stacked diode embodiments) may be disposed on the LED film stack 105 in substantially the same manner described for the base layers 158, 162 and 163 or in any manner known in the art. Following the growth of the LED film stack 105, the substrate 157 is unloaded from the growth platform and conventional patterning and etching techniques are performed to expose regions of the bottom n-type GaN layers (e.g., top surface of base layers 158) and the p-type epitaxial layers 163. Any contact metallization known in the art may then be applied to the exposed regions to form n-type electrode contact and p-type electrode contacts for the LED film stack 105. In exemplary embodiments, the n-type electrode is made of a metal stack, such as, but not limited to, Al/Au, Ti/Al/Ni/Au, Al/Pt/Au, or Ti/Al/Pt/Au. Exemplary p-type electrode embodiments include Ni/Au or Pd/Au. For either n-type or p-type contacts, a transparent conductor, such as Indium Tin Oxide (ITO), or others known in the art, may also be utilized.

FIG. 1C is a flow diagram illustrating a multi-chambered epitaxial growth process 110 for the formation of the GaN-based LED film stack depicted in FIG. 1B. The multi-chambered epitaxial growth process 110 further describes the pre-growth chamber seasoning performed during the LED film stack growth, in accordance with an embodiment of the present invention. A substrate is loaded into a multi-chamber deposition system. In the depicted embodiment, the substrate, like substrate 157, is ready for growth of the base layer 158. The base layer 158, including a complementarily doped layer (e.g., n-type) is then grown in a deposition chamber of the multi-chamber deposition system at operation 160. For alternative embodiments, where the substrate already includes the entire base layer 158 as a starting material, the multi-chambered epitaxial growth process 110 may skip the operation 160.

At operation 171, a first deposition chamber 405 is in an idle state during which no substrate is present or being transferred to/from the first deposition chamber 405. While in the idle state, the first deposition chamber 405 waits for the substrate 157 to become available for processing. In one embodiment, during the idling operation 171 the first deposition chamber 405 performs a pump/purge by flowing an inert source gas while pumping the chamber to a subatmospheric pressure. Any conventional pump/purge may be performed with an exemplary process being a nitrogen purge with the chamber pumped down to 50-100 Torr. Depending on the duration of growth process performed in different chambers of the multi-chambered deposition system, the first deposition chamber 405 may remain idle at operation 171 for 30 minutes or more while waiting for the substrate 157. For example, in the multi-chambered epitaxial growth process 110 the first deposition chamber 405 is idled at operation 171 while at least a portion of the MQW structure 162 is grown in a second deposition chamber 415 at operation 161.

At operation 164, the second deposition chamber 415 executes a deposition process to epitaxially grow a portion of the LED film stack. In the exemplary LED film stack 105, an undoped top barrier layer is grown at operation 164 over the MQW structure 162. As such, the second deposition chamber 415 performs the operations 161 and 164 on the substrate 157 successively. Upon completion of operation 164, the substrate 157 is transferred to the first deposition chamber 405 for growth of a doped layer at operation 165. Depending on the duration of the operations 161 and 164, the first deposition chamber 405 is idled at operation 171 for a time and then a seasoning operation 173 is initiated by the first deposition chamber 405 prior to the second deposition chamber 415 completing operation 164.

At operation 173, the first deposition chamber 405 is seasoned with a source gas containing a first dopant in preparation for executing an epitaxial growth process to form a layer that is doped with the first dopant over the substrate 157. The seasoning process is to be performed with either no substrate or a dummy substrate is disposed in the first deposition chamber (i.e., not in the presence of a product substrate under manufacture). In the exemplary embodiment, the seasoning process is performed with no carrier present in the first deposition chamber 405. It has been found that idling of a chamber which is to perform a doped layer growth, particularly p-type doped layers, may induce a lag in dopant incorporation of the grown film such that the dopant is initially depleted. Generally, the seasoning process is to coat portions of the first deposition chamber 405 with the first dopant species reduce the tendency for a deficiency in the incorporation of the first dopant upon commencement of growing a doped layer on the workpiece. It has been found that a chamber showerhead can be coated with dopant species by flowing a source gas containing the dopant species, and that, under typical idle chamber conditions, a chamber will hold residual dopant species for a duration thereafter to an extent that initial dopant depletion is reduced relative to when no seasoning is performed between idling and depositing films on a product substrate.

For the embodiment depicted in FIG. 1C in which the first deposition chamber 405 is to grow a p-type doped group III-Nitride (e.g., a magnesium doped epitaxial layer 163), a magnesium-containing source gas is introduced into the first deposition chamber 405 during the seasoning operation 173. While any conventional magnesium-containing source gas may be utilized, the exemplary source gas is cp₂Mg. For the seasoning operation 173, the dopant containing source gas may be introduced alone or along with other gas sources. For example, each of the source gases that will be utilized in the doped layer growth operation 165 may be introduced during seasoning. In an embodiment where the first deposition chamber 405 is to grow a p-GaN epitaxial layer 163, a gallium-containing source gas, a nitrogen-containing source gas, and a reducing source gas, are introduced during the seasoning operation 173 in addition to the magnesium-containing source gas. For example, the gallium-containing source gas may be TMGa, the nitrogen-containing source gas may be NH₃, and the reducing source gas may be H₂. With these source gases, the seasoning process may be run at substantially the same process conditions as employed during the doped layer growth operation 165. For example, any of process pressure, process temperature, and source gas flow rates, may be the same during the seasoning process as during the doped layer growth operation 165.

FIG. 1D illustrates a timing diagram for processes performed by a multi-chambered deposition system, in accordance with an embodiment of the present invention. In FIG. 1D, time is on the x-axis and different chambers (first deposition chamber 405, second deposition chamber 415, and third deposition chamber 416) of a multi-chambered deposition system on the y-axis. At time T₀, the first deposition chamber 405 is in an active state, growing a doped layer of an LED film stack on first substrate (e.g., doped layer growth operation 165) while the second deposition chamber 415 is in an active state growing another portion of an LED film stack on a second substrate (e.g., MQW structure 162 with an undoped top barrier layer). The third deposition chamber 416 is in an idle state.

For the embodiment depicted in FIG. 1D, the MQW growth operation 161 and undoped layer growth operation 164 are performed in the second deposition chamber 415 until time T₁, which may be, for example, 2-3 hours after time T₀. In the mean time, at time T₂, the first deposition chamber 405 completes a doped layer growth operation 165, which may be, for example 1 hour, or less. At time T₁, the first deposition chamber 405 enters an idle state (e.g., operation 171). At time T₂, the first deposition chamber 405 initiates the chamber seasoning operation 173, which is performed until approximately time T₁ (e.g., seasoning terminated in time for the first deposition chamber 405 to be ready to receive a substrate transfer from the second deposition chamber 475). As denoted by the dashed arrows, at time T₁, the second substrate is transferred from the second deposition chamber 415 to the first deposition chamber 405 and the doped layer growth operation 165 is performed to form a p-type doped layer (e.g., Mg-doped GaN) on the second substrate to complete the LED film stack 105. At time T₄, the second substrate is unloaded from the multi-chamber deposition system.

As further depicted in FIG. 1D, over the course of duration D_{G}, the third deposition chamber 416 transitions directly from an extended idle period to perform a complementarily doped layer growth operation 160 which terminates at some time prior to T₁. Because certain doped layer growths display little chamber history effects (e.g., n-type dopant species for GaN), a pre-growth seasoning process is not performed in the third deposition chamber 416.

Depending on the embodiment, initiation of the seasoning operation 173 (e.g., T₃ in FIG. 1D) may be identified by a deposition chamber controller or a controller of a multi-chamber deposition system based one or more of: an elapsed idle time (e.g., D_{I} in FIG. 1D), an elapsed growth time for an upstream deposition chamber (e.g., D_{G} in FIG. 1D), or a time to completion for an upstream deposition chamber process (e.g., T₁). For example, in one embodiment, a controller of the first deposition chamber 405 may cause the first deposition chamber to perform pump/purges for a predetermined idle time and then trigger the seasoning operation 173 after D_{I}. As an alternative example, a controller of a multi-chamber deposition chamber may issue a command to a controller of the first deposition chamber 405 to trigger the seasoning operation 173 at T₃ based on a system event, such as a signal from a controller of the second deposition chamber 415 indicative of T₁. Based on that signal, the system controller may determine T₃ to synchronize a predetermined seasoning process time D_{S}. The system controller may then send a signal to the first deposition chamber 405 at T₃ to initiate the seasoning operation 173.

Once initiated, a deposition chamber controller or controller of the multi-chamber deposition system executes the seasoning operation 173 for a predetermined fixed duration, or terminates the seasoning process based on at least one of: growth time for an upstream deposition chamber (e.g., D_{G}), or a time to completion for an upstream deposition chamber process (e.g., T₁). For example, in one embodiment, a controller of the first deposition chamber 405 may cause the first deposition chamber to perform the seasoning operation 173 for the predetermined fixed time D_{S} (e.g., between 30 and 60 minutes). As an alternative example, a controller of a multi-chamber deposition chamber issues a command to a controller of the first deposition chamber 405 to terminate the seasoning operation 173 at T₁ based on a system event, such a signal from a controller of the second deposition chamber 415 indicative of T₁. Based on that event, the system controller may then send a signal to the first deposition chamber 405 at T₁ to terminate the seasoning operation 173.

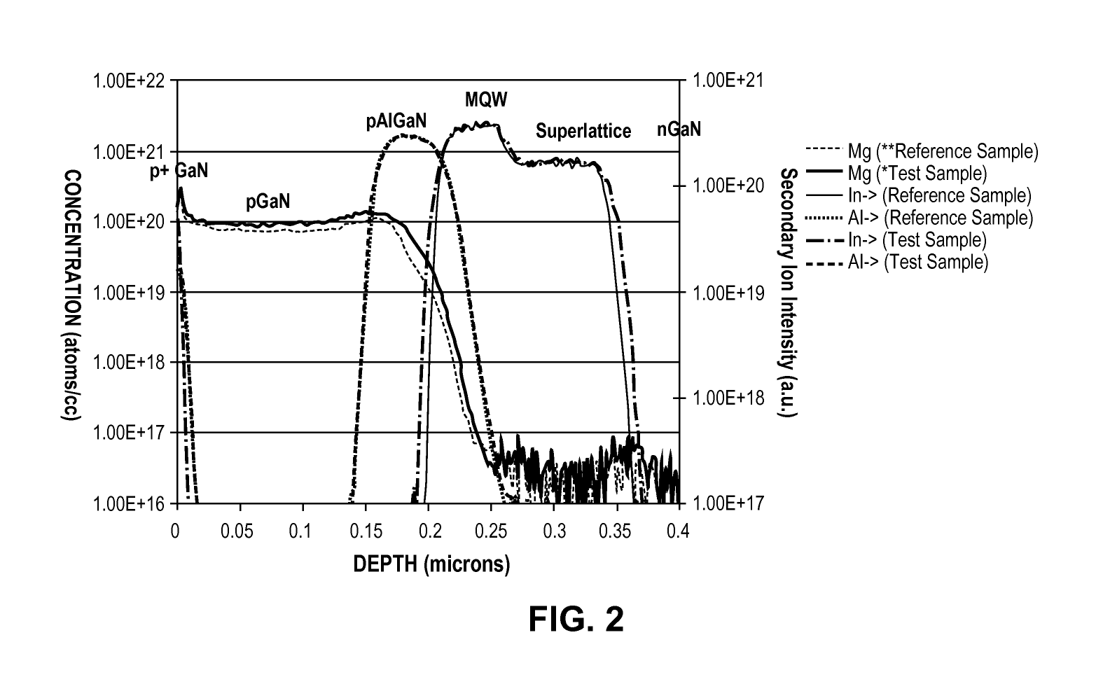

FIG. 2 illustrates a dopant concentration profile, in accordance with an embodiment of the present invention. The illustrated secondary ion mass spectrometry (SIMS) graph depicts a comparison of a “test” LED film stack, such as LED film stack 105, in which a p-type epitaxial layer 163 was grown in a dedicated pGaN chamber with Cp2Mg seasoning and a “reference” LED film stack grown in the same manner except with no seasoning. At evident in FIG. 1E, inflection point of the pGaN profile (between 0.2 and 0.25 μm depth), there is a faster increase in the Mg concentration and reduced Mg depletion when chamber seasoning is performed.

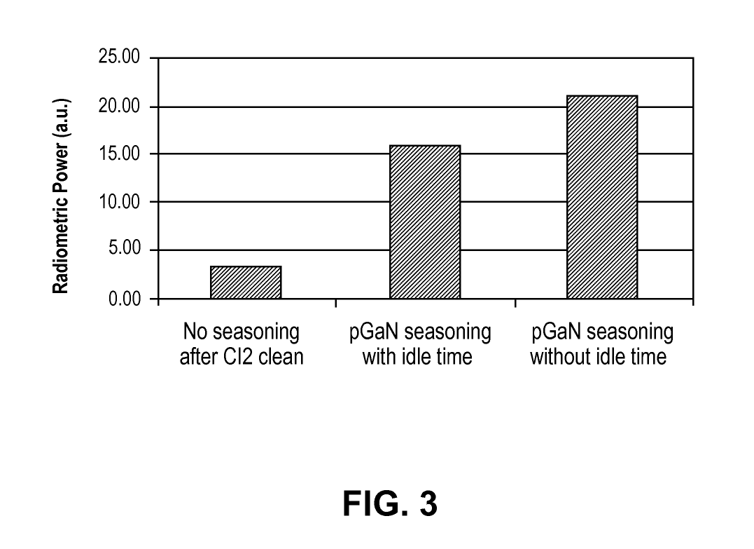

FIG. 3 illustrates a graph of radiometric power for a pGaN layer, in accordance with an embodiment of the present invention. As shown, when a seasoning process is performed just prior to receiving a substrate and performing a p-type doped GaN layer growth, the electroluminescence (EL) measurement quantifies a higher radiometric power than for conditions where a chamber is allowed to remain idle for a period of approximately 1.5 hours prior to receiving a substrate and performing a p-type doped layer growth. As further illustrated, when no seasoning process is performed after an deposition chamber clean (e.g., Cl₂-based in-situ clean), radiometric power is further depressed. Hence, not only does a post-clean seasoning process impart benefits to a doped layer growth, so too does pre-seasoning a chamber which has been idled at some time prior to the growth (e.g., idled after a post-clean seasoning process, as illustrated for the multi-chambered deposition processes described herein).

In embodiments, idling, seasoning and growth of the various epitaxial layers described for the LED film stack 105 may be performed by a MOCVD chamber, a hydride/halide vapor phase epitaxy (HVPE) chamber or any other deposition chamber technology known in the art to be suitable for epitaxial growth of film stacks, such as the LED film stack 105. Exemplary systems and chambers that may be adapted to practice the present invention are described in U.S. patent application Ser. No. 11/404,516, filed on Apr. 14, 2006, and Ser. No. 11/429,022, filed on May 5, 2006, both of which are incorporated by reference in their entireties.

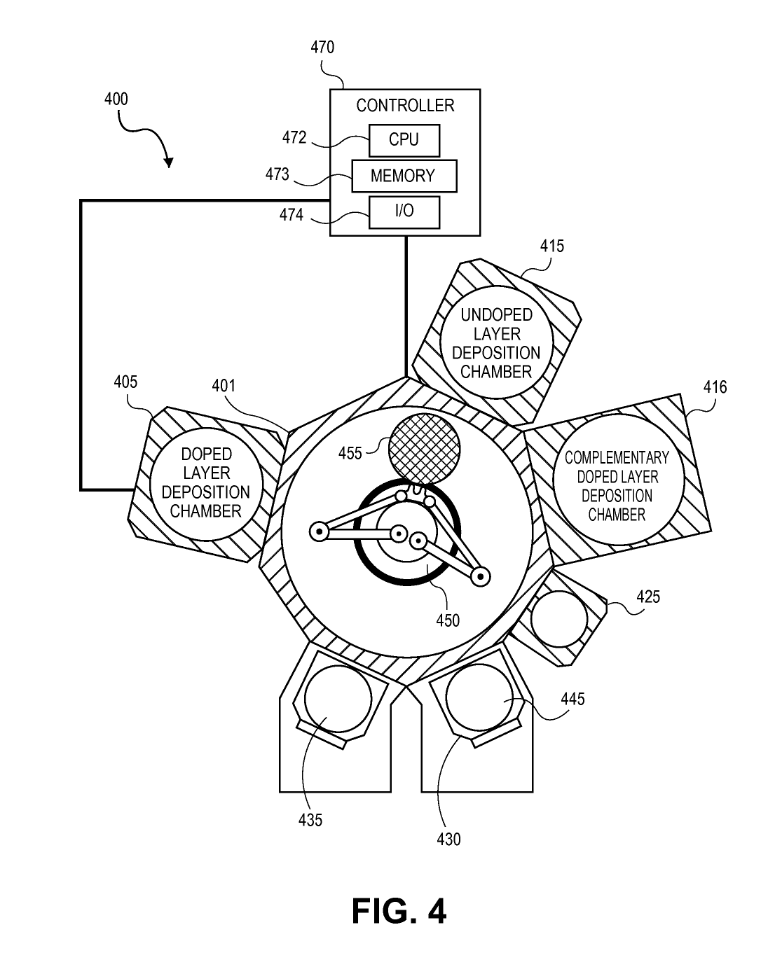

As shown in FIG. 4, two or more epitaxy chambers, such as two or more MOCVD chamber or two or more HVPE chambers, or a combination of MOCVD and HVPE chambers, are coupled to a platform to form a multi-chambered deposition system 400. Embodiments described herein which utilize an intra-LED film stack transfer of the substrate between two epitaxy chambers may be performed using the multi-chambered deposition system 400. Referring to FIG. 4, the multi-chambered deposition system 400, may be any platform known in the art that is capable of adaptively controlling a plurality of process modules simultaneously. Exemplary embodiments include an Opus™ AdvantEdge™ system or a Centura™ system, both commercially available from Applied Materials, Inc. of Santa Clara, Calif.

The first, second, and third deposition chambers 405, 415, and 416 perform particular growth operations on a substrate 455, as described elsewhere herein. In the exemplary embodiment, the deposition chambers 405, 415, and 416 are separately dedicated to growth of doped layers growths (e.g., Mg doped layers) in the first deposition chamber 405, and growth of Mg-free films in the other chambers (e.g., MQW and undoped barrier layers in the second deposition chamber 415 and/or n-type doped films in the third deposition chamber 416). As further depicted in FIG. 4, the multi-chambered processing platform 400 further includes an optional substrate integrated metrology (IM) chamber 425, as well as load lock chambers 430 holding cassettes 435 and 445, coupled to the transfer chamber 401 including a robotic handler 450.

In one embodiment of the present invention, control of the multi-chambered processing platform 400, including the robotic handler 450, is provided by a controller 470. The controller 470 may be a system level controller, in which case it is in control of events in the transfer chamber 401 and may also be in communication with chamber-level controllers associated with each of the deposition chambers 405, 406 and 416. In other embodiments the controller 470 is a chamber level controller, in which case it is in control of events occurring only in a particular deposition chamber (e.g., the first deposition chamber 405). In embodiments, the controller 470 is to cause the first deposition chamber to execute a seasoning process introducing a source gas containing the first dopant into the first deposition chamber while either no substrate or a dummy substrate is disposed in the first deposition chamber. The controller 470 may be one of any form of general-purpose data processing system that can be used in an industrial setting for controlling the various subprocessors and subcontrollers. Generally, the system controller 470 or deposition chamber controller includes a central processing unit (CPU) 472 in communication with a memory 473 and an input/output (I/O) circuitry 474, among other common components. Software commands executed by the CPU 472, cause the multi-chambered processing platform 400 to, for example, load a substrate into the first deposition chamber 405, execute a first growth process, transfer the substrate to the second deposition chamber 415 and execute a second growth process.

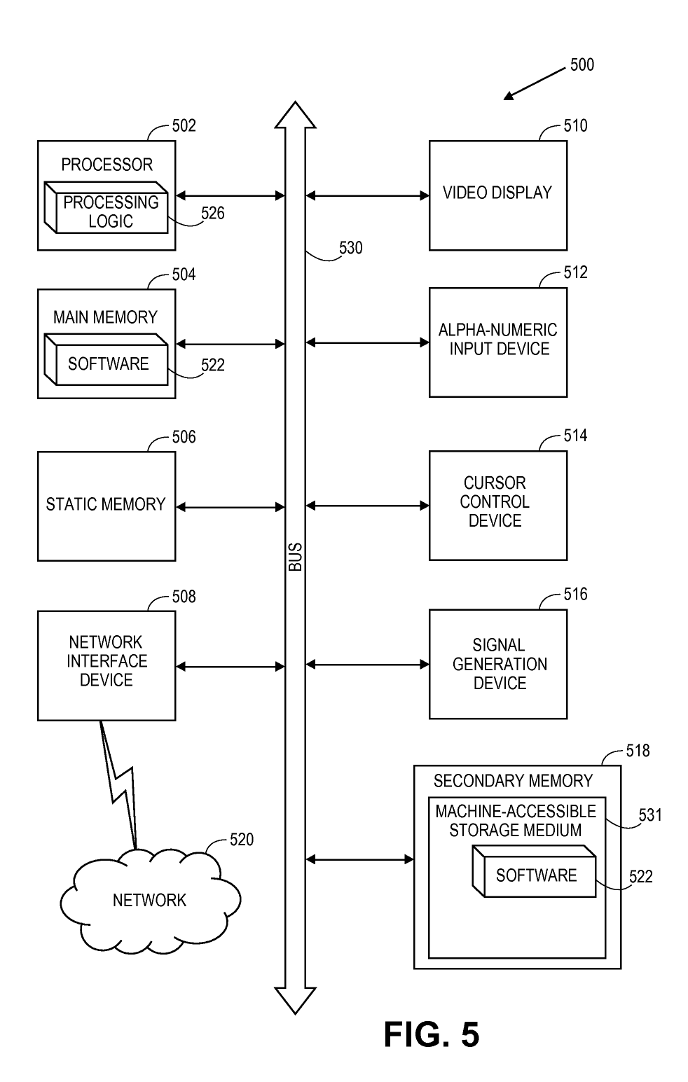

FIG. 5 illustrates a diagrammatic representation of a machine in the exemplary form of a computer system 500 which may be utilized to control one or more of the operations, process chambers or multi-chambered processing platforms described herein. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC) or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The exemplary computer system 500 includes a processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

The processor 502 represents one or more general-purpose processing devices such as a microprocessor, central processing unit, or the like. More particularly, the processor 502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. The processor 502 may also be one or more special-purpose processing devices such as an application specific integrated circuit (ASIC), a field programmable gate array (FPGA), a digital signal processor (DSP), network processor, or the like. The processor 502 is configured to execute the processing logic 526 for performing the process operations discussed elsewhere herein.

The computer system 500 may further include a network interface device 508. The computer system 500 also may include a video display unit 510 (e.g., a liquid crystal display (LCD) or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium (or more specifically a computer-readable storage medium) 531 on which is stored one or more sets of instructions (e.g., software 522) embodying any one or more of the methods or functions described herein. The software 522 may also reside, completely or at least partially, within the main memory 504 and/or within the processor 502 during execution thereof by the computer system 500, the main memory 504 and the processor 502 also constituting machine-readable storage media.

The machine-accessible storage medium 531 may further be used to store a set of instructions for execution by a processing system and that cause the system to perform any one or more of the embodiments of the present invention. Embodiments of the present invention may further be provided as a computer program product, or software, that may include a machine-readable storage medium having stored thereon instructions, which may be used to program a computer system (or other electronic devices) to perform a process according to the present invention. A machine-readable storage medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, and other such non-transitory storage media known in the art.

It is to be understood that the above description is intended to be illustrative, and not restrictive. Many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration. Accordingly, the specification and drawings are to be regarded in an illustrative sense rather than a restrictive sense.

What is claimed is:

1. A method for growing an LED film stack, comprising:
seasoning a first deposition chamber which has been idle after epitaxially growing a layer doped with a first dopant, the seasoning performed with a source gas containing the first dopant while either no substrate or a dummy substrate is disposed in the first deposition chamber; and
epitaxially growing, in the first deposition chamber, a doped layer of the LED film stack on a substrate, the doped layer comprising the first dopant.

2. The method of claim 1, further comprising:
loading the substrate into a multi-chambered deposition system comprising the first deposition chamber and at least a second deposition chamber;
epitaxially growing a portion of the LED film stack over the substrate in the second deposition chamber while seasoning the first deposition chamber.

3. The method of claim 1, wherein the first deposition chamber has been idle for at least 30 minutes.

4. The method of claim 3, wherein idling of the first deposition chamber further comprises:
pumping the first deposition chamber to a subatmospheric pressure while introducing an inert purge gas into the first deposition chamber.

5. The method of claim 4, further comprising performing an initial seasoning of the first deposition chamber after performing an in-situ chamber clean and before the first deposition chamber is idled.

6. The method of claim 2, wherein the source gas further comprises a magnesium-containing source gas.

7. The method of claim 6, wherein the magnesium-containing source gas further comprises Cp2Mg.

8. The method of claim 6, wherein seasoning the first deposition chamber further comprises introducing a gallium-containing source gas, a nitrogen-containing source gas, and a reducing source gas in addition to the magnesium-containing source gas.

9. The method of claim 8, wherein the gallium-containing source gas comprises TMGa, the nitrogen-containing source gas comprises NH₃, and the reducing source gas comprises H₂.

10. The method of claim 5, wherein the chamber seasoning is performed for between 30 and 60 minutes.

11. The method of claim 6, wherein growing the portion of the LED film stack further comprises growing an un-doped GaN layer, and wherein growing the doped layer further comprises growing a magnesium doped pGaN or pAlGaN layer over the un-doped GaN layer.

12. The method of claim 1, further comprising:
growing a complementary doped layer in a third deposition chamber of the multi-chambered deposition system prior to growing the doped layer.

13. A system for processing a substrate, the system comprising:
a first deposition chamber to grow a doped epitaxial layer over the substrate, the doped epitaxial layer containing a first dopant;
a second deposition chamber to grow an undoped epitaxial layer over a substrate; and
a controller to cause the first deposition chamber to execute a seasoning process introducing a source gas containing the first dopant into the first deposition chamber while either no substrate or a dummy substrate is disposed in the first deposition chamber.

14. The system as in claim 13, wherein the controller is further to execute an inert gas purge in the first deposition chamber prior to executing the seasoning process and to execute growth of the doped epitaxial layer after executing the seasoning process.

15. The system as in claim 13, further comprising a third deposition chamber configured to epitaxially grow a complementarily doped layer before or after growth of the doped epitaxial layer.

16. The system as in claim 13, wherein the first and second chambers are both configured for MOCVD, wherein the dopant is Mg and wherein no source gas containing Mg is coupled to the second deposition chamber to maintain the second deposition chamber substantially free of Mg.

17. The system as in claim 13, wherein the first deposition chamber includes a heating lamp, and wherein the controller is to cause the heating lamp to be energized during execution of the chamber seasoning process.

18. The system as in claim 13, wherein the controller is to initiate execution of the seasoning process based on at least one of: an elapsed idle time of the first deposition chamber, an elapsed growth time for an upstream deposition chamber, or a time to completion for an upstream deposition chamber process.

19. The system as in claim 13, wherein the controller is to define a duration of the seasoning process or is to terminate the seasoning process based on at least one of: an elapsed growth time for an upstream deposition chamber, or a time to completion for an upstream deposition chamber process.

20. A computer-readable non-transitory storage medium having stored thereon a set of instructions which when executed cause a system to perform the method of claim 1.
